(19) United States
(12) Patent Application Publication
(10) Pub. No.: US 2003/0157269 A1
(43) Pub. Date: Aug. 21, 2003

(54) Method and apparatus for precision coating of molecules on the surfaces of materials and devices

(75) Inventors: Buddy D. Ratner, Seattle, WA (US); Frank Turecek, Seattle, WA (US); William T. Elam, Redmond, WA (US); Hak-No Lee, Edmonds, WA (US); Kathryn J. Kitching, Seattle, WA (US)

Correspondence Address: SEED INTELLECTUAL PROPERTY LAW GROUP PLLC, 701 FIFTH AVE, SUITE 6300, SEATTLE, WA, 98104-7092, US

(73) Assignee: University of Washington, Seattle, WA (US)

(21) Appl. No.: 10/081,990

(22) Filed: Feb. 20, 2002

(51) Int. Cl. H05H 1/00; C23C 16/00

(52) U.S. Cl. 427/535; 427/256; 118/719; 118/723 R; 118/723 E; 118/723 I; 118/723 MW

(57) ABSTRACT

A method and apparatus for plasma treatment and deposition of ionized molecules on a surface of an object in a vacuum. In one embodiment the apparatus comprises a vacuum system having a plasma-treatment system and an ion deposition system.

### BACKGROUND OF THE INVENTION

1. Field of the Invention

The present invention is directed generally toward a method and apparatus for precision coating of molecules on the surfaces of materials and devices and specifically to the application of ionized molecules in the gas phase onto a plasma-treated surface.

2. Description of the Related Art

Electrospray ionization is used to inject very large molecules into mass spectrometers and can be used in air to fabricate thin films of large biomolecules while retaining their activity. Electrospray ionization can produce ionized molecules in the gas phase which can then be introduced into a vacuum system, where they can be manipulated via ion optics and deposited onto a surface. See, e.g., Cole, R. B. (Ed.), Electrospray Ionization Mass Spectrometry, Wiley, New York (1997); Matsuo, T., et al., J. Mass Specrom, 35, 114-130 (2000); Morozova, T., et al., Anal. Chem. 71, 1415-1420 (1999). Very large molecules, such as molecules of 100 kiloDaltons to 1 megaDalton, can be transported into the gas phase using solution electrospray. This includes molecules that decompose at temperatures below the vaporization temperature, such as enzymes and large sugars, including hyaluronic acid. Smaller molecules may also be transported into the gas phase using solution electrospray.

Other sources for generating ionized molecules in the gas phase include Atmospheric Pressure Chemical Ionization (APCI), Fast-Atom Bombardment (FAB), modified FAB sources, including Liquid Secondary Ion Mass Spectrometry (LSIMS) and Continuous FAB sources, and Matrix-Assisted Laser Desorption Ionization (MALDI). Ionized molecules in the gas phase produced by such methods can also be introduced into a vacuum system, manipulated via ion optics, and deposited onto a surface. It is difficult and not always possible, however, to achieve the desired density of molecules on the surface of an object with conventional technologies.

Plasma treatments provide a diverse range of surface modification possibilities and are environmentally friendly and economical in their use of materials. Plasma treatment has the following features that are by no means mutually exclusive. Plasma treatment can be used to breakdown surface oils and loose contaminates. For metal surfaces, plasma treatment can leave the surface truly “cleaned” down to the base metal. However, using a number of plasma parameters reactive functionalities or dangling bonds may be obtained in a wide variety of substrate materials. Plasma treatment also permits micro-roughening of a surface. Surface conditions can also be altered by the substitution or addition of new chemical groups from the active species created in the plasma. Process gases such as O₂, N₂, He, Ar, NH₃, N₂O, CO₂, CF₄ and air or some combination thereof are most commonly used for activation purposes, although a host of others may be successfully utilized.

Plasma treatment can also be used to deposit other materials onto surfaces, such as thin polymeric films. See Ratner, B., Ultrathin Films (by Plasma Deposition), 11 Polymeric Materials Encyclopedia 8444-8451 (1996). Polymers are very large molecules created when many smaller links of monomer molecules are joined. Plasma treatment can create polymer films from materials that do not form polymers by conventional wet chemistry techniques. The surface can be coated with polymeric substances of controlled molecular weight, chemical polarity or other reactivity. Plasmas can fractionate feed gases without linkable sites into a variety of new and reactive compounds that may subsequently polymerize. Structure in plasma polymers can be varied by, inter alia, using co-reactants or introducing O₂, N₂ or NH₃ into the reaction chamber during polymerization to incorporate specific atomic species. See Schram, D., et al., 62 Polymeric Mat. Sci. Eng. 25 (1990). See also Smolinsky, G., et al, Symposium on Plasma Chemistry of Polymers p. 105, edited by M. Shen (Marcel Decker, Inc., New York, 1976). Plasma treatment is an effective surface treatment for different sample shapes, sizes, materials, and geometries.

It can be appreciated that there is a significant need for an improved system and method for depositing ionized molecules onto a surface. The present invention provides this and other advantages, as will be apparent from the following detailed description and accompanying figures.

### BRIEF SUMMARY OF THE INVENTION

The present invention is embodied in a method and apparatus for depositing ionized molecules in a gas phase, such as large biomolecules, onto a surface and for plasma-treating the surface. In one embodiment, the method comprises transferring ionized molecules to a vacuum, plasma-treating the surface in the vacuum, and controlling the deposition of the ionized molecules on the surface in the vacuum. In that embodiment, the apparatus may comprise a vacuum system comprising a plasma treatment system, an ion deposition system, which may comprise ion guiding optics, to guide the ionized molecules to the target surface, and a target guiding system, to position a target surface in the ion guiding system and the plasma treatment system.

### BRIEF DESCRIPTION OF THE SEVERAL VIEWS OF THE DRAWING(S)

FIG. 1 is a functional block diagram of one embodiment of an apparatus for implementing the present invention.

FIG. 2 is a functional block diagram of an embodiment of an apparatus for implementing the present invention employing an electrospray injector system to provide a source of ionized molecules.

FIG. 3 is a functional block diagram for an electrospray injector system for use in one embodiment of the present invention.

FIG. 4 is a flow chart illustrating the operation of one embodiment of the present invention.

FIG. 5 is a cross-sectional view of a surface treated by a method embodying the present invention.

FIG. 6 is a cross-sectional view of another surface treated by a method embodying the present invention.

### DETAILED DESCRIPTION OF THE INVENTION

The present invention is embodied in a method and apparatus for depositing ionized molecules in a gas phase, such as large biomolecules, onto a surface of an object and for plasma-treating the surface.

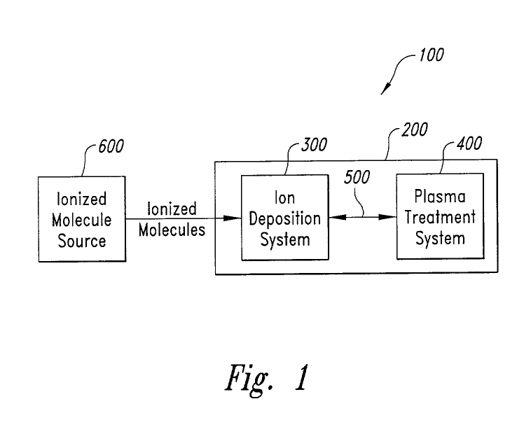

The present invention is embodied in an apparatus 100 illustrated in the functional block diagram of FIG. 1. The apparatus 100 includes a vacuum system 200, an ion deposition system 300, a plasma treatment system 400 and a target guiding system 500. The apparatus may also include an ionized molecule source 600 to provide ionized molecules of the desired type, such as ionized hyaluronic acid or ionized enzymes, to the ion deposition system 300, which is contained within the vacuum system 200.

Sources of ionized molecules are well known in the art and include the following: Electrospray Injection; Atmospheric Pressure Chemical Ionization (APCI); Fast-Atom Bombardment (FAB); Liquid Secondary Ion Mass Spectrometry (LSIMS); Continuous FAB; and Matrix-Assisted Laser Desorption Ionization (MALDI). Ionized molecules can be produced from various sources, such as solutions of biopolymers, and can be singly or multiply charged cations and/or anions. Production of ionized molecules is not the subject of this invention and thus, with the exception of a description of a particular electrospray injection system used in an embodiment of the invention for purposes of illustration, need not be discussed in detail herein. After reviewing the specification, one of skill in the art would be able to select an appropriate source for the desired ionized molecules with little or no experimentation. For example, one of skill in the art might consider using an APCI source if it was desired to deposit ionized esters or ketones on the surface of an object, as APCI is known in the art to produce ionized esters and ketones. One of skill in the art will also recognize that the ionized molecule source 600 may utilize ion optics and other techniques to facilitate the providing of ionized molecules to the ion deposition system 300 in the vacuum system 200.

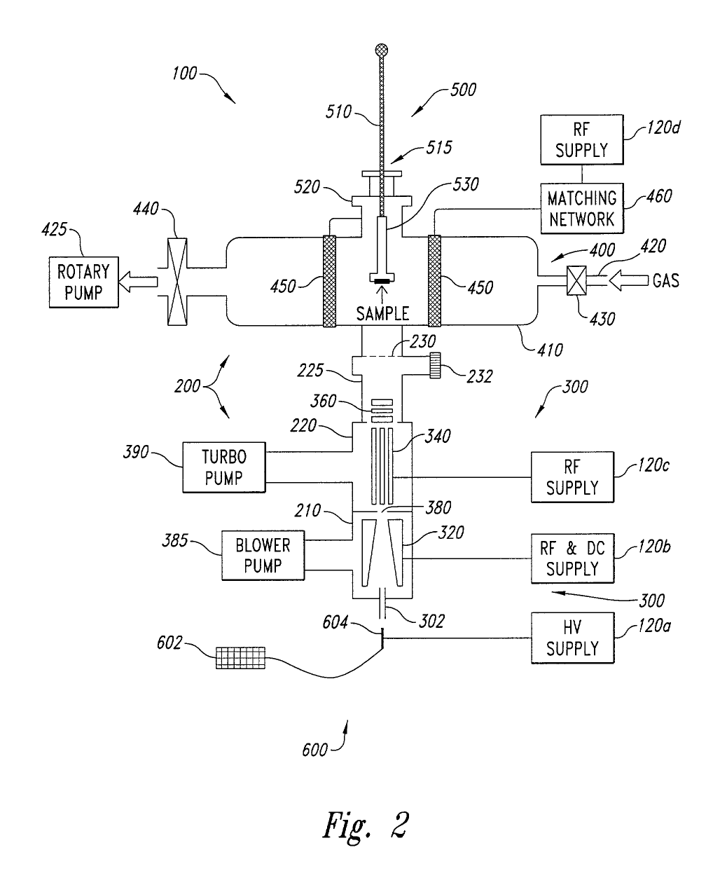

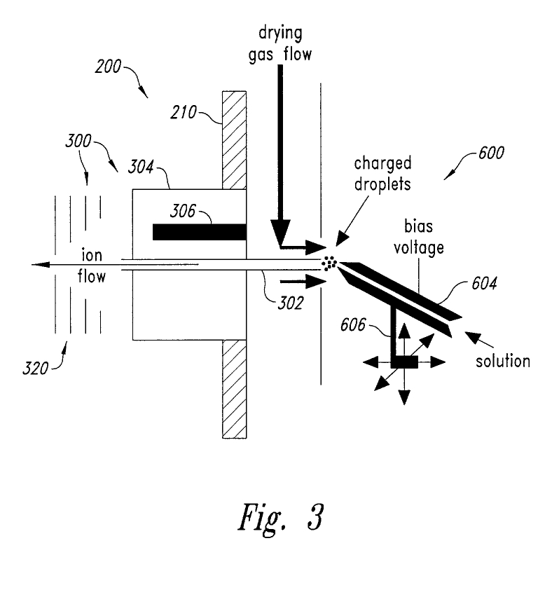

FIGS. 2 and 3 illustrate an electrospray ionization system suitable for use as the ionized molecule source 600 for the ion deposition system 300. A syringe pump 602 pumps a solution through a spray capillary 604. The solution will typically contain the desired molecules and a solvent. Commercially available syringe pumps capable of low flow rates, such as the Fisher KDS-100, and equivalents will perform satisfactorily as the syringe pump 602. A stainless steel capillary of approximately 0.25 mm inner diameter which is tapered approximately 30° to a point at the spray end will perform as the spray capillary 604. One of skill in the art will recognize that equivalent spray mechanisms may be used. An inlet capillary 302 is positioned near the spray capillary 604 to transfer ionized molecules to the ion deposition system 300. A glass-lined stainless steel capillary with an inner diameter of 0.8 mm and a length sufficient penetrate the vacuum system wall will function appropriately as an input capillary 302. Spacing of the spray capillary 604 with respect to the inlet capillary 302 impacts the performance of the apparatus 100. Accordingly, the spray capillary 604 can be placed on a multi-coordinate manipulator, such as an XYZ manipulator 606, to facilitate control of the distance and positioning.

The apparatus 100 has a power supply system 120 to supply various RF and DC voltages required by the components of the apparatus 100. A bias voltage of a relatively large value is generated by the power supply system 120a and applied to the spray capillary 604 with respect to the inlet capillary 302. The high voltage components of the power supply system 120 should be able to recover from occasional discharges and arcs. In testing, the commercially available Bertan Model 230-05R performed in a satisfactory manner. After reviewing this specification, one of skill in the art could select appropriate commercially available components for the power supply system 120. The bias voltages should be positive or negative, depending on the characteristics of the molecules to be ionized. For the embodiment illustrated in FIGS. 2 and 3, satisfactory ionization occurs when a voltage of plus or minus approximately 1000 volts DC is applied to the spray capillary 604 and a voltage of plus or minus approximately 500 volts DC is applied to the inlet capillary 302. The spray capillary 604 may be electrically isolated by an insulator (not shown) such as 50 mm ceramic standoff insulator.

The inlet capillary 302 may be mounted in a capillary mounting block 304 (see FIG. 3) in a chamber wall 210 of the vacuum system 200. The capillary mounting block 304 may contain a heater 306 (such as the commercially available Scientific Instrument Services 3618K421). Typically, the inlet capillary 302 may be heated to approximately 100° C. Drying gas, such as nitrogen, flows past the heater 306 and in the opposite direction of the charged droplets emerging from the spray capillary 604, which are carried by the electric field to the inlet capillary 302. The use of drying gas helps to reduce the amount of solvent contained in the spray mixture which is sucked into the vacuum system 200 and provides a clean gas to be sucked into the vacuum system 200. The amount of flow may be measured by a variable area flow gauge (such as a Cole-Palmer U-32458-50) (not shown). The ionized molecule source 600, which as shown in FIGS. 2 and 3 as an electrospray injection system, may be covered by an insulating shield (not shown) with an interlock switch (not shown) to the power supply system 120, to improve the safety of the apparatus 100.

In the embodiment shown in FIG. 2, the ion deposition system 300 comprises an inlet capillary 302, an ion funnel 320, a multipole ion guide 340, electrostatic lenses 360 (such as deflection and Einzel lenses), an aperture 380, and pumps 385, 390. The ion deposition system 300 guides ionized molecules to the surface of the object on which it is desired to deposit ionized molecules. As discussed in more detail below, the ion deposition system 300 may also remove solvents and undesired gases. The ion deposition system 300 shown in FIG. 2 may be configured to guide the ions to specific locations on the surface of the object. Thus, when used in combination with the target guiding system 500, it is possible to deposit ionized molecules in patterns on the surface of the object with the ion deposition system 300. Additional ion guides, lenses, and apertures, as well as magnetic fields, may be employed to fine-tune the ability of the ion deposition system 300 to guide ionized molecules to specific surfaces on an object. Further, the ion current can be measured to determine the amount of material deposited on the surface of the object.

The ion funnel 320 may consist of a radio frequency funnel lens, such as the lens disclosed in U.S. Pat. No. 6,107,628. Another ion funnel design is disclosed by Lynn, E. C., et al, 14 Rapid Comm. Mass. Spectrom 2129-2134 (2000). Ion funnels are known in the art. After reviewing this specification, one skilled in the art would be able to design or select an appropriate ion funnel 320 with little or no experimentation. Although not required for the present invention, use of an ion funnel 320 is useful because it facilitates achieving high ionized molecule transmission rates.

In the embodiment shown in FIG. 2, a DC gradient applied along the ion funnel 320 propels ionized molecules toward the small end of the ion funnel 320. An RF voltage applied along the ion funnel 320 produces an effective radial potential, which moves the ions toward the axis of the ion funnel 320. The axis of the ion funnel 320 is shown as a dashed line in FIG. 2. As the ionized molecules are swept through the ion funnel 320 by the DC potential, they collide with background gas molecules and lose kinetic energy. As a result the ionized molecules arrive at the end of the ion funnel 320 with relatively low momentum. The energy level of the ionized molecules may be increased if desired by applying a bias voltage to the surface of the object. The vacuum chamber 210 containing the ion funnel 320 is pumped by a blower 385, which maintains the vacuum against the conductance of the inlet capillary 302. The pumping also helps to remove solvent and dry gases. Additional differential pumping of the vacuum system 200 can be employed to remove additional solvent and dry gas from the apparatus 100.

An aperture 380 follows the ion funnel 320, with the axis of the aperture 380 aligned with the axis of the ion funnel 320. The aperture 380 facilitates differential pumping and may be biased to continue the DC potential gradient in the ion funnel 320. The aperture 380 can also be biased to collect the current emerging from the ion funnel 320 to allow the funnel operating parameters to be optimized. The outlet side of the aperture 380 is aligned with the axis of the multipole ion guide 340. The ion guide 340 may be operated in RF-only mode. The RF voltage on the ion guide 340 serves to confine the ions to the center of the multipole ion guide 340. A DC potential could also be applied to the multipole ion guide 340, either in combination with an RF potential or as an alternative to the RF potential.

The surface (identified as a sample in FIG. 2) on which ionized molecules are to be deposited is placed close to the exit of the multipole ion guide 340 when it is desired to deposit ionized molecules on the surface of the object. A distance of less than 2 mm will help to minimize the impact of stray electric and magnetic fields. A holder comprised of a suitable material (not shown) may be placed in front of the ion guide 340 to promote accurate alignment of the surface with the axis of the multipole ion guide 340. The vacuum in the ion guide chamber 220 is maintained by a turbo pump 390. The pumping helps to remove solvent and dry gas. The ends of the multipole ion guide 340 may protrude slightly from the ion guide chamber 220 into the ion deposition chamber 225 to facilitate positioning the sample surface close to the exit of the multipole ion guide 340. The multipole ion guide 340 may be an octapole ion guide.

In the embodiment shown in FIG. 2, an ion deposition chamber 225 is between the ion guide chamber 220 and a plasma reactor chamber 410. The ion deposition chamber 225 may be closed-off from the plasma reactor chamber 410 through the use of a gate 230 operable by a gate valve 232.

The plasma treatment system 400 of the embodiment of the apparatus 100 shown in FIG. 2 is similar to those described in Ratner, B. D., “Ultrathin Films by Plasma Deposition”, in Polymeric Materials Encylcopedia, Volume 11, Joseph C. Salamone, Ed., CRC Press, Boca Raton, 1006, and comprises the plasma reactor chamber 410 with a gas inlet 420 at one end and vacuum pump 425 at the opposite end. The inlet gas flow is controlled by a mass flow controller 430. The pressure is measured by a capacitance manometer (not shown) and regulated to a preset value by a throttle valve 440. Typical values of the flow and pressure are 10 sccm and 250 mTorr, respectively. The tuning of the throttle valve 440 is not critical and the factory values may be used. The use of flexible couplings, such as metal bellows (not shown) will prevent strain on the plasma reactor chamber 410 which may be made of glass. A cold trap (not shown) to trap volatile gasses and a burst disk (not shown) to prevent over-pressurization of the plasma reactor chamber 410 may also be present in the vacuum system for the plasma treatment system 400. The rotary pump 425 for the plasma treatment system 400 may contain an appropriate lubricant to avoid damage from pumping oxygen. The plasma is generated by applying a radio frequency signal from the power supply system 120d through a matching network 460 to a plurality of electrodes 450 in the plasma reactor chamber 410. The electrodes 450 may be arranged in various geometries to obtain the desired plasma characteristics.

Although the embodiment shown in FIG. 2 illustrates a plasma treatment system 400 employing a RF plasma generator, other plasma generators may be used, including audio frequency, microwave and direct current plasma generators.

The target guiding system 500 moves the target surface between the plasma treatment system 400 and the ion deposition system 300 within the vacuum system 200. In the embodiment shown in FIG. 2, the target guiding system 500 moves the target between the plasma reaction chamber 410 and the ion deposition chamber 225 and properly positions the target surface in the appropriate chamber. Thus, the target guiding system 500 allows the target surface to be alternately subjected to plasma treatment and to deposition of ionized molecules without leaving the vacuum system 200. The target guiding system may comprise a positioning member operable to position the surface of the object to be treated. For example, mechanical motors (not shown) could be employed to position the object in response to control commands.

In the embodiment shown in FIG. 2, the target guiding system 500 comprises a glass tube 510 which enters the plasma reactor chamber 410 through an o-ring fitting 515 in a kwik-flange port 520. The o-ring fitting 515 allows the glass tube 510 to slide along its length, thus moving the target surface as necessary. The glass tube 510 is capped with a glass to metal seal with a threaded cap (not shown). A ceramic sample holder 530 screws onto the cap, allowing various sized objects and mounting mechanisms to be utilized.

A cable (not shown) can be slid inside the tube 510 to make contact with the sample holder 530, or the target surface can be left floating. This provides for flexibility in arranging the geometry of the plasma electrodes 450 to achieve the desired plasma configuration without interference from the cable while still providing for measurement of the sample current during deposition of ionized molecules. The kwik flange port 520 allows for easy changing and repositioning of the object whose surfaces are to be treated by the apparatus.

After reviewing this specification, one of skill in the art will recognize that the apparatus 100 and method illustrated in FIG. 2 may be modified with little or no experimentation to accommodate objects of different shapes and sizes and with different properties and to achieve specific coating characteristics. For example, ion optics can be employed to control or steer the trajectories of the ionized molecules, if spatial control of a spot on the target on which ionized molecules are to be deposited is desired. Additional manipulation of the object can be employed, such as rotation of the object. Movement of the object in conjunction with the steering or focusing of the ion trajectory permits coating of the surface of an object in a specific pattern, if desired. Multiple coatings may be applied and the object may be subjected to multiple plasma treatments. Additional differential pumping can be employed to permit introduction of an object from the ambient atmosphere into the apparatus for processing and removal to the ambient atmosphere after processing, such as an air-to-vacuum-to-air interface. These modifications may be particularly useful for medical devices with a porous, irregular design, such as vascular grafts, stents, sutures and other devices used in interventional medical procedures. In addition, the ion optic and differential pumping configurations can be modified to increase the ability to separate solvents, if increased purity of the deposited material is desired.

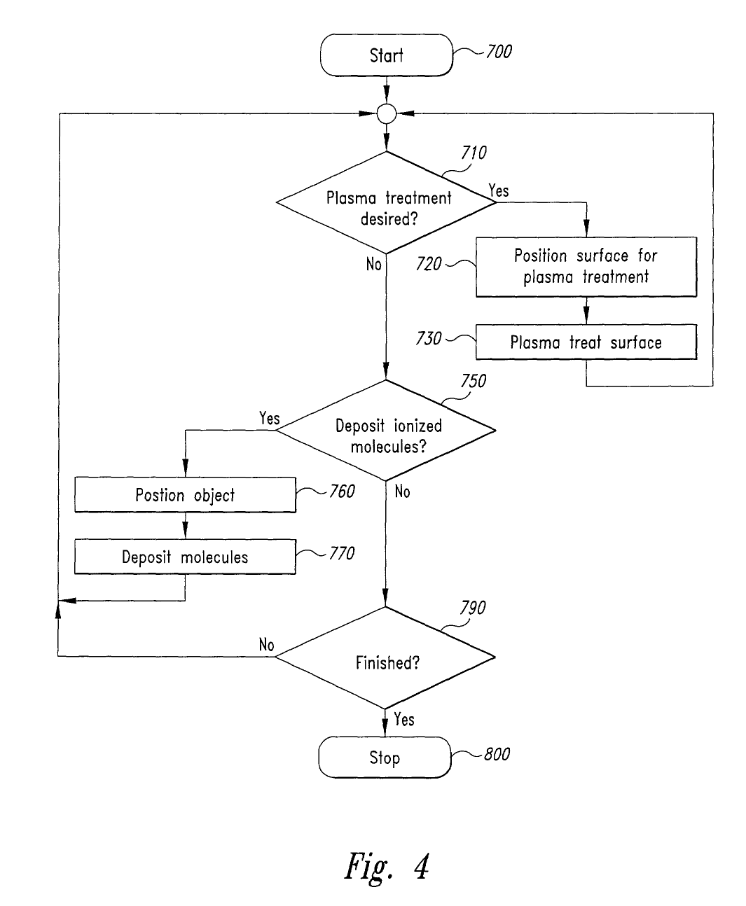

FIG. 4 is a flow chart illustrating operation of an embodiment of the present invention. At a start 700 the apparatus is initialized. At step 710, it is determined whether plasma treatment is desired. If the answer at step 710 is YES, the surface is positioned for plasma treatment in step 720 followed by plasma treatment in step 730. The apparatus then returns to step 710 for further processing if desired.

If the answer at step 710 is NO, the apparatus proceeds to step 750, where it is determined whether deposition of ionized molecules is desired. If the answer at step 750 is YES, the surface is position for deposition of ionized molecules in step 760 and ionized molecules are deposited in step 770. The apparatus then returns to step 710 for further processing if desired.

If the answer at step 750 is NO, the apparatus proceeds to step 790, where it is determined whether processing of the object is finished. If the answer at step 790 is YES, processing is stopped at step 800. If the answer at step 790 is NO, the apparatus returns to step 710 for further processing if desired.

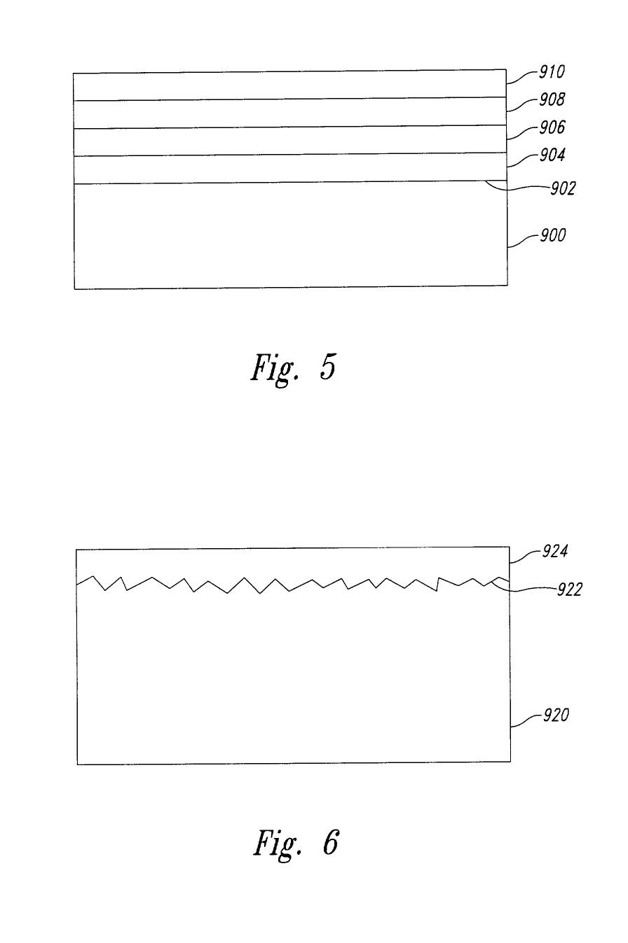

FIG. 5 illustrates an embodiment of an object 900 prepared using an embodiment of the method of the present invention. Layer 904 comprises ionized molecules deposited on a surface 902 of the object 900. Layer 906 comprises a polymer layer deposited in plasma treatment on the surface 902 of the object 900. Layer 908 comprises a second polymer layer deposited in plasma treatment. Layer 910 comprises an additional layer of ionized molecules deposited on the surface 902 of the object 900. Thus, as FIG. 5 illustrates, multiple layers may be deposited on a surface 902 of a object 900 and plasma treatment and ionized molecule deposition can occur in various sequences.

FIG. 6 illustrates another embodiment of a object 920 treated using an embodiment of the method of the present invention. A surface 922 of the object was micro-roughened using plasma treatment. Then a layer 924 of ionized molecules was deposited on the plasma treated surface 922.

All of the above-referenced U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. In addition, after having reviewed this specification, one of skill in the art would be able to ascertain suitable substitutes for the specific examples of equipment referred to in the specification. Accordingly, the invention is not limited except as by the appended claims.

1. An apparatus for depositing ionized molecules onto a target surface of an object in a vacuum system, the apparatus comprising:
an ion deposition system for depositing the ionized molecules onto the target surface;
a plasma treatment system for plasma-treating the target surface; and
a target guiding system to guide the target surface within the vacuum.

2. The apparatus of claim 1, further comprising an ionized molecule source.

3. The apparatus of claim 2 wherein the ionized molecule source comprises at least a selected one of the following: an electrospray ionization source; an Atmospheric Pressure Chemical Ionization (APCI) source; a Fast-Atom Bombardment (FAB) source; a Liquid Secondary Ion Mass Spectrometry (LSIMS) source; a Continuous FAB source; or a Matrix-Assisted Laser Desorption Ionization (MALDI) source.

4. The apparatus of claim 1 wherein the ion deposition system is configured to deposit ionized biomolecules.

5. The apparatus of claim 1 wherein the ion deposition system is configured to deposit ionized enzymes.

6. The apparatus of claim 1 wherein the ion deposition system is configured to deposit ionized hyaluronic acid.

7. The apparatus of claim 1 wherein the ion deposition system is configured to deposit ionized sugars.

8. The apparatus of claim 1 wherein the ion deposition system is configured to deposit ionized molecules onto a stainless steel surface.

9. The apparatus of claim 1 wherein the ion deposition system is configured to deposit ionized molecules onto a surface of polymeric material.

10. The apparatus of claim 1 wherein the ion deposition system comprises an ion optics system.

11. The apparatus of claim 1 wherein the ion deposition system comprises an ion funnel.

12. The apparatus of claim 1 wherein the ion deposition system comprises a multipole ion guide.

13. The apparatus of claim 1 wherein the target guiding system comprises a connection for applying a biasing voltage to the target surface.

14. The apparatus of claim 1 wherein the plasma treatment system comprises a radio frequency plasma generator.

15. The apparatus of claim 1 wherein the plasma treatment system comprises an audio frequency plasma generator.

16. The apparatus of claim 1 wherein the plasma treatment system comprises a microwave plasma generator.

17. The apparatus of claim 1 wherein the plasma treatment system comprises a direct current plasma generator.

18. The apparatus of claim 1 wherein the plasma treatment system comprises:
a gas introduction system having mass flow controllers;
a reaction chamber;
a plasma generator; and
a pumping system.

19. The apparatus of claim 18 wherein the pumping system comprises a contamination trap, a throttle value, vacuum gauges, and a feedback control.

20. The apparatus of claim 1 wherein the target guiding system comprises a positioning member, the positioning member being operable to position the target surface within the apparatus.

21. The apparatus of claim 1 wherein the target guiding system is configured to move and thereby position the target surface within the plasma treatment system and within the ion deposition system.

22. The apparatus of claim 1 wherein the ion deposition system comprises:
an ion funnel;
a pump;
a multipole ion guide;
ion current sensors; and
a deposition chamber.

23. An apparatus for depositing ionized molecules on a target surface, the apparatus comprising:
a deposition chamber in a vacuum system;
an electrospray injector to generate ionized molecules and inject them into the vacuum system;
an ion optics system in the vacuum system to guide ionized molecules to the deposition chamber;
a plasma reactor in the vacuum system to treat the target surface; and
a target surface transfer system to position the target surface within the apparatus.

24. The apparatus of claim 23 wherein the electrospray injector comprises:
a syringe pump to pump molecules;
a spray capillary connected to the syringe pump to spray pumped molecules;
a high voltage power supply system to maintain a bias voltage on the spray capillary with respect to a bias voltage on the ion optics system and to ionize sprayed molecules; and
a drying gas source to provide drying gas;
wherein the spray capillary and the ion optics system are positioned so that drying gas and ionized molecules are propelled into the vacuum system via the ion optics system.

25. The apparatus of claim 24 wherein the spray capillary is mounted on a multi-coordinate manipulator to manipulate the position of the spray capillary with respect to the ion optics system.

26. The apparatus of claim 24 wherein the ion optics system has an inlet capillary mounted in a mounting block comprising a heater and thermocouple and the drying gas flows past the heater and in the opposite direction to the spray from the spray capillary.

27. The apparatus of claim 23 wherein the ion optics system comprises:
an ion funnel having an axis; and
a multipole ion guide having an axis;
wherein the ion funnel is biased with a DC potential gradient to propel ionized molecules through the ion funnel, a RF voltage is applied to the ion funnel to move ion molecules toward the axis of the ion funnel, and the multipole ion guide is positioned to receive ionized molecules from the ion funnel.

28. The apparatus of claim 27 wherein the ion optics system further comprises a pump, wherein the electrospray injector injects a solvent as well as ionized molecules into the vacuum system and the pump removes solvents from the vacuum system.

29. The apparatus of claim 27 further comprising an aperture having an axis and positioned between the ion funnel and the multipole ion guide.

30. The apparatus of claim 29 wherein a bias voltage is applied to the aperture.

31. The apparatus of claim 29 wherein the axes of the ion funnel, the multipole ion guide and the aperture are aligned.

32. The apparatus of claim 27 wherein the multipole ion guide is controlled by a RF voltage.

33. The apparatus of claim 27 wherein the multipole ion guide is controlled by a DC bias voltage.

34. The apparatus of claim 27 wherein the multipole ion guide is an octapole ion guide.

35. The apparatus of claim 23 wherein the plasma reactor comprises:
a chamber having a gas inlet at one end and a vacuum pump at an opposite end;
a mass flow controller to control a gas flow through the gas inlet;
a pressure regulation system; and
a plasma generator.

36. The apparatus of claim 35 wherein the plasma generator comprises a plurality of electrodes in the reactor.

37. The apparatus of claim 35 wherein the pressure regulation system comprises a capacitance manometer and a throttle valve.

38. The apparatus of claim 23 wherein the target surface transfer system comprises a positioning member operable to position the target surface within the apparatus.

39. The apparatus of claim 23 wherein the target surface transfer system comprises an electrical coupling to the target surface.

40. The apparatus of claim 38 wherein the positioning member is biased with a bias voltage.

41. The apparatus of claim 23 further comprising a gate between the plasma reactor and the deposition chamber, and a gate valve to open and close the gate.

42. A method of depositing ionized molecules on a surface of an object in a vacuum system, the method comprising:
plasma-treating the surface of the object in the vacuum system; and
depositing ionized molecules on the surface of the object in the vacuum system.

43. The method of claim 42 wherein the surface of the object is plasma-treated prior to depositing ionized molecules on the surface of the object.

44. The method of claim 42 wherein ionized molecules are deposited on the surface of the object prior to plasma-treatment of the object.

45. The method of claim 42 further comprising generating ionized molecules by at least one the following methods: electrospray ionization; Atmospheric Pressure Chemical Ionization (APCI); Fast-Atom Bombardment (FAB); Liquid Secondary Ion Mass Spectrometry (LSIMS); Continuous FAB; and Matrix-Assisted Laser Desorption Ionization (MALDI).

46. The method of claim 42 wherein depositing ionized molecules comprises: introducing ionized molecules into the vacuum system; and guiding ionized molecules to the surface of the object.

47. The method of claim 46 wherein guiding ionized molecules comprises funneling ionized molecules using an ion funnel.

48. The method of claim 46 wherein guiding ionized molecules includes using multipole ion optics.

49. The method of claim 42, further comprising separating solvents from ionized molecules.

50. The method of claim 42, further comprising separating dry gas from ionized molecules.

51. The method of claim 42, further comprising measuring an ion current.

52. The method of claim 42, further comprising controlling an ion kinetic energy level of ionized molecules.

53. The method of claim 52 wherein the kinetic energy level is controlled by adjusting an electrostatic potential of the surface.

54. The method of claim 42, further comprising heating the surface of the object.

55. The method of claim 42, further comprising exposing the surface of the object to ultraviolet activation.

56. The method of claim 42, further comprising positioning the surface of the object to facilitate plasma-treatment and depositing of ionized molecules.

57. The method of claim 42 wherein the plasma-treatment comprises at least one of the following: plasma etching of the surface; opening of micropores of the surface; micro-roughening of the surface; coating the surface with polymeric substances; and plasma cleaning of the surface.

58. The method of claim 42 wherein the plasma-treatment produces dangling bonds on the surface.

59. The method of claim 42 wherein the plasma-treatment comprises substitution of chemical groups on the surface.

60. The method of claim 42 wherein the plasma-treatment comprises addition of chemical groups onto the surface.

61. The method of claim 42 wherein the plasma-treatment comprises treatment with at least one of the following as a process gas: O₂, N₂, N₂O, He, Ar, NH₃, CO₂, CF₄ and air.

62. The method of claim 42, further comprising controlling the plasma treatment by adjusting a power input to a plasma-generator.

63. The method of claim 42, further comprising controlling the plasma treatment by adjusting a gas-flow rate to a plasma-generator.

64. The method of claim 42, further comprising controlling the plasma treatment by changing a type of gas feed to a plasma-generator.

65. The method of claim 42 wherein the object is irregularly shaped.

66. The method of claim 42 wherein the surface on which ionized molecules are deposited is a stainless steel surface.

67. The method of claim 42 wherein the surface on which ionized molecules are deposited is a surface of polymeric material.

68. The method of claim 46 wherein guiding of ionized molecules comprises generating potential fields.

69. The method of claim 42 wherein the ionized molecules comprise biomolecules.

70. The method of claim 42 wherein the ionized molecules comprise enzymes.

71. The method of claim 42 wherein the ionized molecules comprise hyaluronic acid.

72. The method of claim 42 wherein the ionized molecules comprise sugar.

73. The method of claim 42 wherein the object is a medical device.

74. A medical device produced using the method of claim 42.

75. The method of claim 42, further comprising manipulating the object to deposit ionized molecules on an additional surface of the object.

76. The method of claim 75 wherein ionized molecules are deposited on the object in a pattern.

77. The method of claim 46 wherein guiding ionized molecules comprises using an electrostatic lens.

78. The method of claim 42, further comprising manipulating the object through an air-to-vacuum-to-air differentially pumped interface.

79. The method of claim 46 wherein guiding ionized molecules comprises generating a magnetic field.

80. The method of claim 46 wherein guiding ionized molecules comprises using an aperture.

81. The method of claim 42 wherein the object is a long, thin object.

82. An object having a surface coated with molecules applied using the method of claim 42.

83. An object having a surface coated with hyaluronic acid applied using the method of claim 42.

84. The method of claim 42 wherein the plasma treatment comprises coating the surface with a polymeric substance of a controlled molecular weight.

85. The method of claim 42 wherein the plasma treatment comprises coating the surface with a polymeric substance of a controlled chemical polarity.
